(19) United States
(12) Patent Application Publication
(10) Pub. No.: US 2015/0155407 A1
(43) Pub. Date: Jun. 4, 2015

(54) METHODS FOR SUBSTRATE PROCESSING

(71) Applicant: APPLIED MATERIALS, INC., Santa Clara, CA (US)

(72) Inventors: LANCE A. SCUDDER, Sunnyvale, CA (US); CHARLES GAY, Westlake Village, CA (US); JAMES M. GEE, Albuquerque, NM (US); KASHIF MAQSOOD, San Francisco, CA (US); BRIAN H. BURROWS, San Jose, CA (US); TAEJOON PARK, Sunnyvale, CA (US)

(21) Appl. No.: 14/557,696

(22) Filed: Dec. 2, 2014

Related U.S. Application Data
(60) Provisional application No. 61/910,942, filed on Dec. 2, 2013.

(51) Int. Cl. H01L 31/0475; B32B 38/10; B32B 43/00; B32B 37/18

(52) U.S. Cl. CPC H01L 31/0475; B32B 37/18; B32B 38/10; B32B 43/006

(57) ABSTRACT

Methods for processing substrates are provided herein. In some embodiments, the method includes providing a substrate supported on a starting template; adhering a first superstrate to a first side of the substrate; separating the substrate with the superstrate from the starting template; determining if a useful life of the used template has been reached; and re-using the used template as a starting template if the useful life has not been reached.

### CROSS-REFERENCE TO RELATED APPLICATIONS

This application claims benefit of U.S. provisional patent application Ser. No. 61/910,942, filed Dec. 2, 2013, which is herein incorporated by reference in its entirety.

### FIELD

Embodiments of the present disclosure generally relate to semiconductor fabrication processes.

### BACKGROUND

Some substrates for semiconductor devices are manufactured by sawing a silicon ingot into substrates. In the sawing process, material is lost due to the blade thickness, or kerf. This loss is sometimes referred to as kerf loss. Substrate production processes that reduce the amount of kerf loss are sometimes referred to as kerfless processes, although some kerf loss may still occur.

One kerfless process includes forming a relief surface on a silicon starting template, epitaxially depositing one or more silicon layers on the relief surface, and separating the epitaxially grown silicon layers, the substrate, from the template. The substrate continues in the manufacturing process, and the template is discarded. Some thin silicon substrates formed using this process may need a support structure, or handle, to facilitate further processing.

The inventors have noted that with the above process the discarded wafer and the additional component of the handle add to material costs in conventional silicon substrate manufacturing.

Accordingly, the inventors provide methods for reducing manufacturing costs in silicon substrate processing using select materials as handles for processing thin substrates or wafers.

### SUMMARY

Methods for processing thin epitaxial wafers are provided herein. In some embodiments, the method includes providing a substrate supported on a starting template; adhering a first superstrate to a first side of the substrate; separating the substrate with the superstrate adhered thereto from the starting template at a separation layer of the starting template to provide a superstrate adhered to the substrate and a used template; and re-using the used template as a starting template. In some embodiments, the method further comprises determining that a useful life of the used template has been reached; and discarding the used template as a discarded template after the useful life has been reached.

In some embodiments, a method for processing a cell includes providing a substrate supported on a starting template; processing a first side of the substrate while the substrate is supported on the starting template; adhering a module glass superstrate to the first side of the substrate after processing the first side; separating the substrate with the glass superstrate adhered thereto from the starting template; and processing a second side of the substrate while the substrate is adhered to the glass superstrate. In some embodiments, a plurality of cells may be made according to the aforementioned method, wherein adjacent cells are positioned such that edges of the module glass of the adjacent cells are arranged in an edge-to-edge relationship and first sides of the module glass are aligned.

Other and further embodiments of the present disclosure are described below.

### BRIEF DESCRIPTION OF THE DRAWINGS

Embodiments of the present disclosure , briefly summarized above and discussed in greater detail below, can be understood by reference to the illustrative embodiments of the disclosure depicted in the appended drawings. It is to be noted, however, that the appended drawings illustrate only typical embodiments of this disclosure and are therefore not to be considered limiting of its scope, for the disclosure may admit to other equally effective embodiments.

FIGS. 1A-1C depict a flow diagram of a method for processing a silicon substrate in accordance with embodiments of the present disclosure.

FIGS. 2A-2I are illustrative views of a substrate during different stages of the method of FIG. 1 in accordance with some embodiments of the present disclosure.

FIG. 3 depicts a solar array formed according to embodiments of the method of FIG. 1 in accordance with some embodiments of the present disclosure.

To facilitate understanding, identical reference numerals have been used, where possible, to designate identical elements that are common to the figures. The figures are not drawn to scale and may be simplified for clarity. It is contemplated that elements and features of one embodiment may be beneficially incorporated in other embodiments without further recitation.

### DETAILED DESCRIPTION

Embodiments of the present disclosure generally relate to methods for processing substrates, and may be useful in processing thin semiconductor substrates. For example and without limitation, the method may be useful for generating silicon substrates, silicon germanium (SiGe) substrates, or gallium arsenide (GaAs) substrates. Embodiments of the disclosed method may be useful in generating other substrates as well. In at least some embodiments, the inventive methods may advantageously affect production costs by reducing or eliminating waste as compared to some conventional processes used to form thin substrates. For the purposes of this disclosure, a thin substrate is one with a thickness of about 300 μm or less. While not intending to be limiting in scope, the inventors have observed that the inventive methods may be particularly advantageous in the fabrication of mono-crystalline silicon substrates which may be useful in, for example, solar cells.

In a typical process for manufacturing a semiconductor substrate, for example a silicon substrate, a wafer is cut from a silicon ingot and further processed. Silicon from the ingot corresponding to the thickness of the blade, or kerf, is lost as waste during the cutting operation. This is sometimes referred to as kerf loss. Substrate manufacturing processes that reduce the kerf loss associated with typical processes are sometimes referred to as kerfless processes.

Some efforts to reduce the cost of silicon substrates have looked to reduction of substrate thickness as a possible route to reduced wafer cost. Some kerfless processes may have the capability of producing thin substrates, and may be able to produce substrates less than 160 μm in thickness. Thin substrates may have reduced structural integrity due at least partially to the reduced material thickness. Supporting the thin substrates with reduced structural integrity during processing has presented a challenge to substrate processing methods.

One approach is to provide a handle to offer additional structural integrity or support to the thin wafer during processing. The handle is removed prior to use of the wafer, for example as a solar cell, and the handle discarded. However, the handle as a disposable item adds to manufacturing costs. The presently disclosed method may reduce, or eliminate, the drawbacks found in the currently used methods.

In some kerfless substrate formation processes, a substrate is formed by depositing an epitaxial layer on a surface of a starting template. The surface may be a modified layer of the starting template, processed to be a continuous single crystal silicon layer separated from the underlying template by a separation layer. The separation layer facilitates separation of the substrate (i.e., the continuous single crystal silicon layer and the epitaxial layer thereon) from the underlying template. The starting template may be formed from any process compatible material, including, as non-limiting examples, silicon and gallium-arsenide. The starting template may be of any convenient shape. For ease of illustration and clarity, the present disclosure will be directed to rectangular starting substrates having a length, width and thickness.

The inventors have observed that substrates formed in the process discussed above may be processed on a first side while supported by the underlying starting substrate. Processing on a second side of the substrate is sometimes beneficial, in which case the substrate is separated from the underlying template to expose the second side. Some substrates, particularly thin substrates, may benefit from support provided by a support structure, or superstrate, during processing following separation of the substrate from the underlying template.

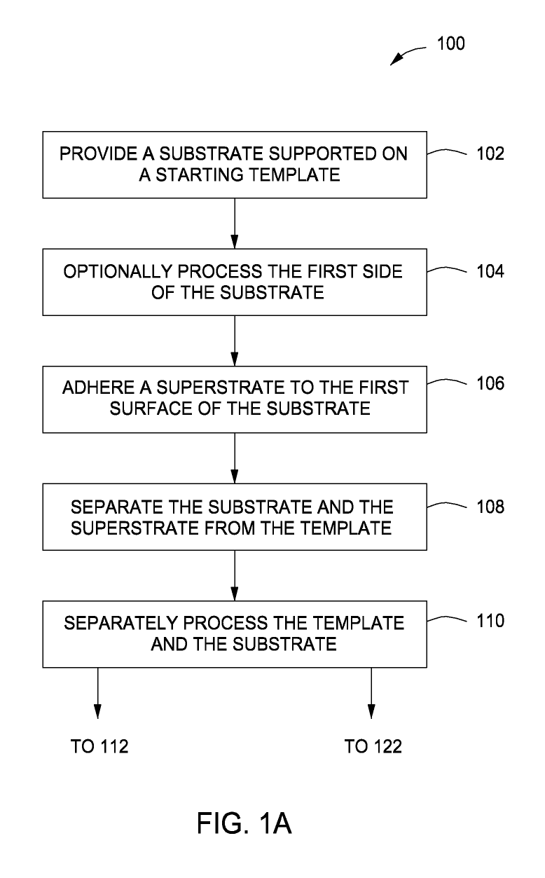

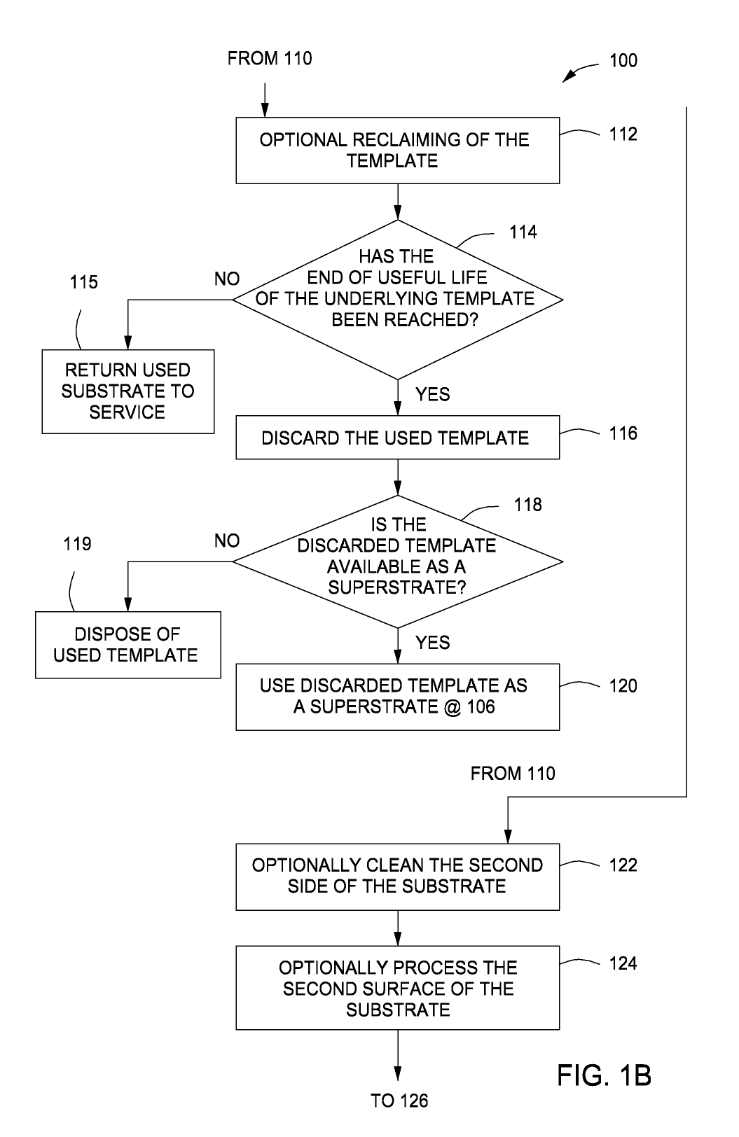

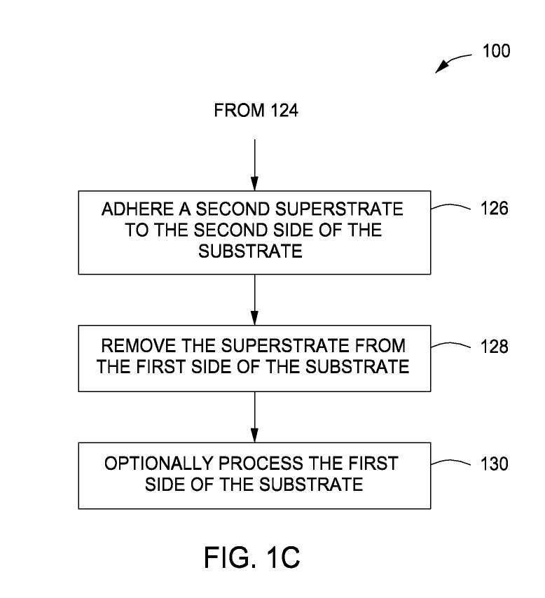

FIGS. 1A-1C are a flow diagram of a method 100 for processing a substrate in accordance with some embodiments of the present disclosure. The method 100 may be performed in any apparatus suitable for processing semiconductor substrates in accordance with embodiments of the present disclosure.

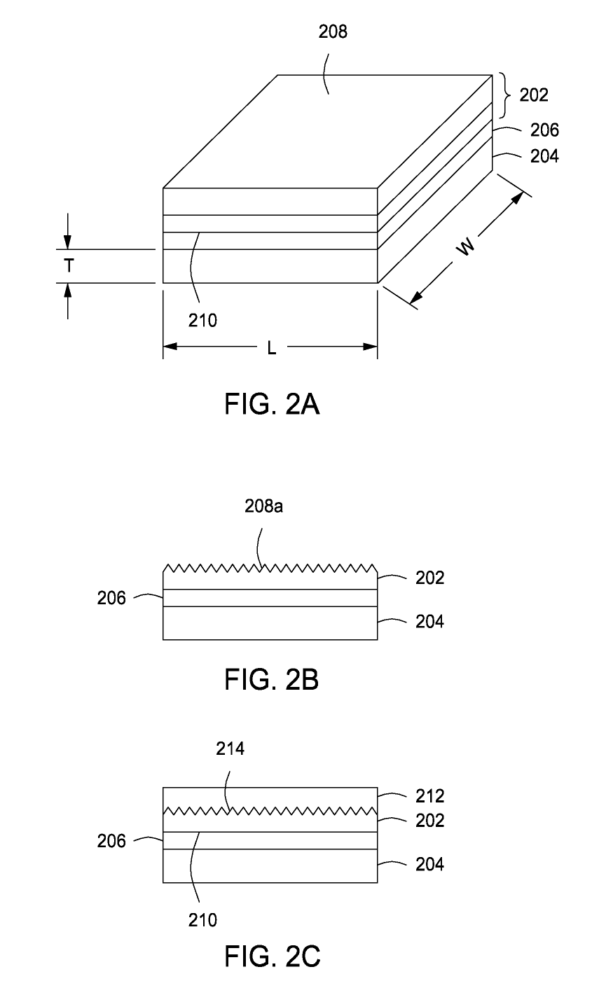

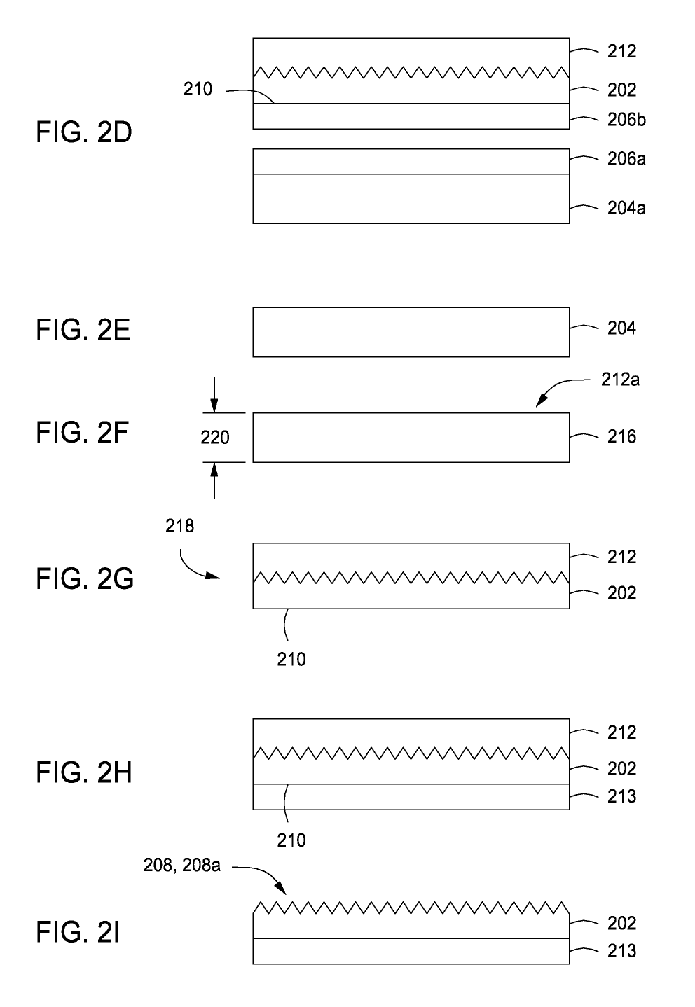

At 102, a substrate 202 supported on a starting template 204 is provided as depicted in FIG. 2A. Between the substrate 202 and the starting template 204 is a separation or release layer 206 to facilitate separation of the substrate 202 from the starting template 204. The substrate has a first side 208 and a second side 210 disposed upon and supported by the release layer 206. The starting template 204 has a length L and a width W with which the edges of the substrate 202 are generally coterminous, and a thickness T. Thicknesses and relative thicknesses of layers illustrated in this disclosure are not to scale and are generally exaggerated for clarity.

At 104, the first side 208 of the substrate 202 is optionally processed. The processing at 104 may include diffusion of an emitter into the first side 208 (and into the substrate 202) or texturing the first side 208 to a first textured surface 208a as shown in a side view in FIG. 2B. Other, or additional, processes may take place at 104. For clarity, the substrate 202 is illustrated in this disclosure as having been optionally processed at 104 to include a first textured surface 208a. The first textured surface 208a is representative of all processes performed on the substrate 202 at 104.

The inventors have noted that substrates 202, particularly if comprised of a thin epitaxial layer, may be subject to stresses during processing or handling that exceed the strength of the substrate 202 and compromise the structural integrity of the substrate 202. In some cases, the substrate 202 may benefit from support during processing, for example additional support provided by the starting template 204 through the release layer 206. For example, the inventors have noted that the support structure (comprising the release layer 206 and the underlying starting template 204) may provide additional support to the substrate 202 to withstand stresses and maintain the integrity of the substrate 202. Various other benefits may also be provided by the support structure.

In some applications, processing of the second side 210 of the substrate 202 may be beneficial. As discussed above, some substrates may benefit from support during processing. A handle, or superstrate, may advantageously be added to the first side 208 (or first textured surface 208a) of the substrate 202 in order to support the substrate 202 for processing of the second side 210.

At 106, a superstrate 212 is adhered to the first side 208 (or first textured surface 208a) as depicted in FIG. 2C. An adhesive 214, for example a light transparent silicone adhesive, may be used to adhere the superstrate 212 to the first side 208 (or 208a). In some embodiments, the adhesive 214 may be non-transparent. Alternately, other adhesives or methods may be used to adhere the superstrate 212 to the first side 208. In some embodiments, a wax, or wax-like substance, may be used as an adhesive 214 between the substrate 202 and the superstrate 212. In some embodiments, the first side 208 (or first textured surface 208a) and a surface of the superstrate 212 to be adhered to the substrate 202 may each be oxidized and an oxide to oxide bond may be formed.

The superstrate 212 may be formed from any process compatible material having sufficient mechanical characteristic (such as, for example, strength, rigidity, or the like) to provide additional support to the substrate 202 during processing of the second side 210 of the substrate 202. The superstrate 212 may provide the same, or similar, benefits for processing the second side 210 as the release layer 206 and the starting template 204 provided for processing the first side 208 of the substrate 202 discussed above.

In some embodiments, the superstrate 212 may be a previously used starting template 204 as will be discussed in greater detail below. In other embodiments, the superstrate 212 may be formed from glass, for example module glass. Module glass includes glass suitable for use on a sunlight facing side (sometimes referred to as the “sunny side”) of a solar cell, or on a sunlight facing side of a plurality of solar cells arranged in an array.

The superstrate 212 may be sized to correspond with the width W and length L dimensions of the starting template 204 and the corresponding dimensions of the substrate 202. In some embodiments, the superstrate 212 may be larger than the starting template 204 and the substrate 202 with the superstrate 212 extending beyond one or more of the lengthwise or widthwise edges. In other embodiments, the superstrate may be similar, or substantially similar, to the size of the substrate 202.

At 108, the substrate 202 with the superstrate 212 adhered thereto are separated from the starting template 204, with the separation occurring at the release layer 206. Once separated, the starting template 204 may be referred to as a used template 204a as depicted in FIG. 2D. In some embodiments, remnants of the release layer 206 may remain with the used template 204a and the substrate 202. For example, as depicted in FIG. 2D, a portion 206a, remains on the used template 204a. Similarly, a portion 206b remains on the second side 210 of the substrate 202.

At 110, the used template 204a and the substrate 202 begin separate processing according to embodiments of the present disclosure.

At 112, the used template 204a is optionally reclaimed in, for example, a cleaning process which may remove, or facilitate the removal of, the portion 206a that remains adhered to the used template 204a after separation. Other deposits on other surfaces of the used template 204a may also be beneficially removed at 112. The process may be an etching process or other suitable cleaning process that may be employed to prepare a used template 204a for reuse as a starting template 204.

In some embodiments, the used template 204a may be used multiple times (e.g., re-used) until the end of a useful life as a starting template 204 is reached. The end of a useful life may be signaled by a physical characteristic of the used template 204a, such as a physical dimension. In many cases, the thickness T of the starting template 204 will decrease with each use. When a minimum thickness T for the starting template 204 to be useful as a starting template is reached, the end of starting template's useful life as a starting template is signaled. A used template 204a may be useful until reaching a thickness of about 250 μm to about 350 μm, or for example about 300 μm (e.g., a prescribed thickness). Alternately, or in conjunction, the length L and width W dimensions may be reduced with each use until the length L and width W are at or below an established minimum acceptable dimension.

In some cases, the end of useful life of a used template 204a may be signaled by a level of contamination found in the used template 204a (e.g., a predetermined level of contamination). Possible sources of contamination could include exposure to process gases or process byproducts, or handling of the used template 204a during multiple uses. In some cases, the useful life of the used template 204a may be determined by a number of process cycles, with or without regard to any physical characteristic of the used template 204a. As a non-limiting example, a useful life for a starting template may be about 100 cycles.

A used template 204a can go through the optional preparation or reclaiming operations at 112 to prepare the template quality for the upcoming processes. Pre-process preparation is optional for a new starting template 204, which may be used directly in the following process. However, a used template 204a may undergo, among other things, chemical mechanical planarization (CMP) or chemical cleaning/polishing steps to produce the flatness and clean starting surfaces sought for subsequent processes.

According to some embodiments of the present disclosure, at 114 certain physical characteristics of the used template 204a are evaluated to assist in determining the availability of the used template 204a as a starting template 204, that is, if the useful life of the used template 204a as a starting substrate 204 has been reached. As discussed above, the end of the useful life of a used template 204a may be signaled by a change in certain physical characteristics, such as the thickness T, the length L, or width W reaching a predetermined value. In some embodiments, the end of the useful life of a used template 204a may be signaled by a level of contamination in the used template 204a, or a number of process cycles or uses of the used template 204a.

In some embodiments, 114 may occur before 112. Some of the signals of an end of useful life can be determined prior to performing the reclaiming operations on the used substrate 204a. In other embodiments, 114 may be performed after 112. In other embodiments, 114 may be performed both before and after 112. For example, at 114 the used substrate 204a may be evaluated for number of process cycles. If the number of cycles is less than the predetermined number of cycles for the end of life signal, then the used substrate 204a passes to 112 for cleaning and then back to 114 to be evaluated for, for example, dimensional characteristics.

If it is determined at 114 that the used template 204a has not reached the end of useful life of a starting template 204, the used template 204a is separated as a starting template 204 (FIG. 2E) and returned to service at 115.

If it is determined at 114 that the used template 204a has reached the end of useful life as a starting template 204, the used template 204a becomes a discarded template 216 (FIG. 2F) at 116.

At 118, the discarded template 216 is evaluated for availability as a superstrate 212. Factors that may determine the availability of the discarded template 216 as a superstrate 212 may include the thickness 220, edgewise and lengthwise dimensions, contamination levels, or other suitable metrics. If the discarded template 216 is not available as a superstrate 212, the discarded template 216 is disposed of at 119. Disposal of the discarded template 216 may include recycling, for example, into a feed stock material for other templates or superstrates.

If the discarded template 216 is available as a superstrate 212, at 120 the discarded template 216 becomes a superstrate 212a and may be provided for re-use at 106 or in a similar manufacturing process.

Separately from, or concurrently with, 112 through 120, portion 206b may be removed from substrate 202 in an optional cleaning process at 122. FIG. 2G depicts the substrate 202 and the superstrate 212 after cleaning at 122. Portion 206b may be similar to the portion 206a discussed above and removed in a similar process. The cleaning process at 122 may be an etching process to remove the portion 206b in preparation for optional further processing. Optional processing of the second side 210 of the substrate 202, with the substrate 202 supported by the superstrate 212, may take place at 124.

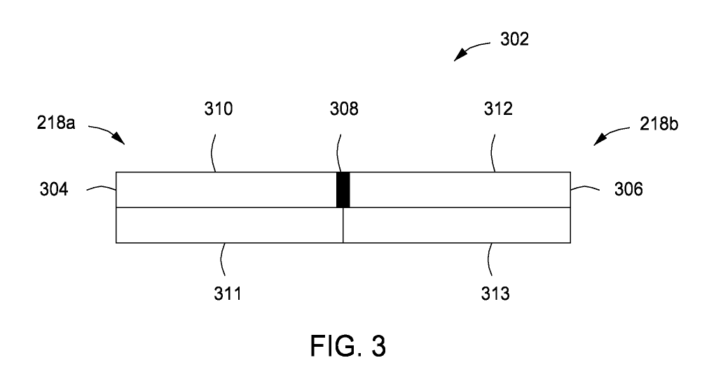

In some embodiments, the superstrate 212 may beneficially be maintained adhered to the substrate 202, forming a cell 218. In some embodiments, the superstrate 212 is formed of glass, for example module glass, and the cell 218 is a solar cell. In such embodiments, widthwise and lengthwise edges of the superstrate 212 may be joined to widthwise and lengthwise edges of one or more additional cells, similar to cell 218, to form an array 302, for example a solar array, depicted in FIG. 3. FIG. 3 depicts two cells forming an array for ease of illustration only. Any number of cells may be joined in the manner described below.

As depicted, two cells 218a and 218b are positioned such that the cell-sized module glass 304 and 306 of cells 218a and 218b, respectively, are in edge-to-edge relationship and the first side 310 of module glass 304 and the first side 312 of module glass 306 are aligned. A sealing element 308 may be placed at the interface between adjacent edges of the module glasses 304, 306 to bond the edges. The sealing element 308 may be an adhesive with sealing properties, or may be a gasket, to seal the first sides 310, 312 of cells 218a, 218b, respectively, from the second sides 311, 313. The seal may be weather tight (for example, resistant to infiltration of air and moisture) or may provide a barrier to dust and debris. In some embodiments, the cells 218a and 218b may be placed in a fixture (not shown) to facilitate positioning, and the sealing element 308 applied to the cells 218a, 218b.

The inventors have noted that in the array 302, the module glass 304, 306 for the cells 218a and 218b may be used as the module glass for the final assembled array 302. In some current practices, an additional module glass, corresponding to the size of the final array, is used and the cells 218a, 218b, are adhered to the additional module glass. By bonding edgewise and lengthwise edges of the cell-sized module glass 304, 306, the extra array-sized module glass is no longer necessary.

In some embodiments, it is beneficial to remove the superstrate 212 from the first side 208 (or from the first textured surface 208a) of the substrate 202. As noted above, some substrates, for example thin epitaxial layers, may benefit from added support during processing or handling. Accordingly, in some embodiments, the substrate 202 may beneficially be supported with a second superstrate 213 prior to removing the superstrate 212.

At 126, and as depicted in FIG. 2H, a second superstrate 213 is adhered to the second side 210 of the substrate 202. The second superstrate 213 may be formed from any of the materials used for the superstrate 212. In some embodiments, for example in solar cells, the second superstrate 213 may be a metal layer which may facilitate integrating a plurality of solar cells into an array. In embodiments using a metal layer as the second superstrate 213, the metal layer may be formed by electroplating or physical vapor deposition (PVD). In some embodiments, the second superstrate 213 may be adhered to the substrate 202 with any suitable adhesive, for example a silicone adhesive or a wax, or other adhesives or adhesive methods, such as oxide to oxide bonding, as described above.

At 128, the superstrate 212 is removed from the substrate 202 as depicted in FIG. 2I exposing the first side 208 (or the first textured side 208a) of the substrate 202. The superstrate 212 may be reclaimed after separation from the substrate 202 and reused as a superstrate in subsequent processes. In some cases, one or both sides of the superstrate 212 may be processed, for example cleaned, to prepare the superstrate 212 for reuse, as appropriate.

At 130, the first side 208 (or the first textured surface 208a) of the substrate 202 may optionally be processed after the second side has been processed at 124. The processing at 130 may be in addition to, or instead of, the optional processing at 104. Following the processing at 130, if appropriate, the substrate 202 disposed on the second superstrate 213 may be incorporated in suitable devices.

While the foregoing is directed to embodiments of the present disclosure, other and further embodiments of the disclosure may be devised without departing from the basic scope thereof.

1. A method for processing a substrate, comprising:
providing a substrate supported on a starting template;
adhering a first superstrate to a first side of the substrate;
separating the substrate with the first superstrate adhered thereto from the starting template at a separation layer of the starting template to provide a first superstrate adhered to the substrate and a used template; and
re-using the used template as a starting template.

2. The method of claim 1, further comprising:
determining that a useful life of the used template has been reached; and
discarding the used template as a discarded template after the useful life has been reached.

3. The method of claim 2, wherein the useful life is determined by a physical characteristic of the starting template.

4. The method of claim 3, wherein the physical characteristic is a dimension of the used template.

5. The method of claim 2, wherein the useful life is determined by at least one of:
a number of process cycles; or
a level of contamination of the used template.

6. The method of claim 2, further comprising:
determining if the discarded template is available as a superstrate;
re-using the discarded template as a superstrate if the discarded template is available as the superstrate; and
disposing of the discarded template if the discarded starting substrate is not available as a superstrate.

7. The method of claim 6, wherein the discarded template is available as a superstrate if a thickness of the discarded template is greater than a prescribed thickness.

8. The method of claim 7, wherein the prescribed thickness is about 250 μm to about 350 μm.

9. The method of claim 6, wherein the discarded template is available as the superstrate if a level of contamination in the discarded template is below a predetermined level of contamination.

10. The method of claim 1, wherein the first superstrate is a discarded template.

11. The method of claim 1, wherein the first superstrate is formed of glass having a length and a width corresponding with a length dimension and a width dimension of the starting substrate.

12. The method of claim 11, wherein the glass is a module glass.

13. The method of claim 1, further comprising:
after separating the substrate with the first superstrate adhered thereto from the template, processing a second side of the substrate.

14. The method of claim 13, wherein the processing of the second side of the substrate comprises a cleaning process.

15. The method of claim 1, further comprising:
processing the first side of the substrate before adhering the first superstrate to the first side.

16. The method of claim 1, further comprising:
adhering a second superstrate to a second side of the substrate after separating the substrate from the starting template.

17. The method of claim 16, further comprising:
separating the first superstrate from the first side of the substrate such that the second superstrate remains adhered to the second side of the substrate.

18. The method of claim 16, further comprising:
processing the first side of the substrate after separating the first side of the substrate form the first superstrate.

19. A method for processing a cell, comprising:
providing a substrate supported on a starting template;
processing a first side of the substrate while the substrate is supported on the starting template;
adhering a module glass superstrate to the first side of the substrate after processing the first side;
separating the substrate with the module glass superstrate adhered thereto from the starting template; and
processing a second side of the substrate while the substrate is adhered to the module glass superstrate.

20. A plurality of cells made according to the method of claim 19, wherein adjacent cells are positioned such that edges of the module glass of the adjacent cells are arranged in an edge-to-edge relationship and first sides of the module glass are aligned.
